(19) United States
(12) Patent Application Publication
(10) Pub. No.: US 2022/0029597 A1
(43) Pub. Date: Jan. 27, 2022

(54) CONTINUOUSLY ADJUSTABLE ANALOG PHASE SHIFTER

(71) Applicant: NanJing Milliway Microelectronics Technology Co.,Ltd., NANJING, JIANGSU (CN)

(72) Inventors: Xiaoliang WU, NANJING, JIANGSU (CN); Chuan GAI, NANJING, JIANGSU (CN)

(21) Appl. No.: 17/298,424

(22) PCT Filed: Oct. 22, 2019
(86) PCT No.: PCT/CN2019/112626

§ 371 Date: May 28, 2021

(30) Foreign Application Priority Data
Dec. 26, 2018 (CN) 201811599518.6

(51) Int. Cl. H03H 7/18

(52) U.S. Cl. CPC H03H 7/18

(57) ABSTRACT

The invention discloses a continuously adjustable analog phase shifter, comprising N series-connected lumped phase shift units, with N≥1, where the ith lumped phase shift unit is a high-pass lumped phase shift unit or a low-pass lumped phase shift unit, with 1≤i≤N. The invention adopts a lumped phase shift unit, and utilizes the advantage of small size of the lumped parametric circuit, thereby allowing the phase shifter to have a compact structure, small area, low cost and convenient integration. The lumped phase shift units in the invention may be selected as all high-pass lumped phase shift units or low-pass lumped phase shift units as appropriate, thereby having a flexible circuit structure that can meet the requirements at various operation frequencies. The lumped phase shift units in the invention may be selected to take the form of series-connected high-pass lumped phase shift unit and low-pass lumped phase shift unit, thereby permitting a wider bandwidth.

### BACKGROUND

### Technical Field

The invention relates to analog phase shifters, and in particular, to a continuously adjustable analog phase shifter.

### Related Art

With the continuous development of active phased array radar and the advent of 5G communication, demand for antenna beam control is increasing, and the research on control circuits has become more in-depth. As an essential component of beam control, the phase shifter has been one of the essential components in the antenna transceiver assembly due to its numerous operation statuses and technical indicators, large footprint, high performance requirements, and difficult design and fabrication. The development of phased array radar poses higher requirements on the bandwidth, phase shift accuracy and integration area of the phase shifter. Therefore, the research on the analog high-performance phase shifter with continuously adjustable phase has great significance and practical application value.

Reflective analog phase shifter techniques based on varactor diodes are widely used in the design of analog phase shifters with continuously adjustable phase. The phase shifter in prior art includes a 3 dB coupler, usually a 3 dB Lange quadrature coupler with a varactor diode loaded at its terminal to achieve continuous phase adjustment. However, the 3 dB coupler has the disadvantages of large area, inconvenient integration, and increased circuit cost, and the traditional reflective circuit can hardly meet the requirements of broadband and miniaturization.

### SUMMARY

Object of the invention: It is an objective of the invention to provide a continuously adjustable analog phase shifter that can overcome the problems of large area, inconvenient integration, increased circuit cost and difficulty in enabling broadband in prior art.

Technical solution: The continuously adjustable analog phase shifter according to the invention includes N series-connected lumped phase shift units, with N≥1, where the ith lumped phase shift unit is a high-pass lumped phase shift unit or a low-pass lumped phase shift unit, with 1≤i≤N.

Further, the high-pass lumped phase shift unit includes a first inductor L1, one end of the first inductor L1 being connected to the anode of a first voltage-controlled varactor diode D1, the cathode of the first voltage-controlled varactor diode D1 being connected respectively to one end of the second inductor L2 and the anode of a second voltage-controlled varactor diode D2, the other end of the second inductor L2 being grounded, the cathode of the second voltage-controlled varactor diode D2 being connected to the other end of the first inductor L1; where one end of the first inductor L1 serves as the input of the high-pass lumped phase shift unit and the other end of the first inductor L1 serves as the output of the high-pass lumped phase shift unit. As can be seen, the high-pass lumped phase shift unit has a simple circuit structure and can provide stable phase shifting in a wide frequency range. Also, due to the mutual coupling effect between the first inductor L1 and the second inductor L2, the overall phase shifter has a compact structure, small area and low cost, and can be widely applied to RF/microwave/millimeter wave band wireless communication systems.

Further, the first inductor L1 and the second inductor L2 are both spiral inductors, thereby allowing the phase shifter to be more compact and have a greater Q value.

Further, the first inductor L1 has an inductance of 2R/ω₀ and the second inductor L2 has an inductance of R/ω₀, and the first voltage-controlled varactor diode D1 and the second voltage-controlled varactor diode D2 both have a capacitance of 1/Rω₀, where R is the input impedance of the phase shifter and coo is the center frequency of the high-pass lumped phase shift unit.

Further, the low-pass lumped phase shift unit includes a third inductor L3, one end of the third inductor L3 being connected to the anode of the third voltage-controlled varactor diode D3, and the other end of the third inductor L3 being connected respectively to one end of the fourth inductor L4 and the cathode of the fourth voltage-controlled varactor diode D4, the anode of the fourth voltage-controlled varactor diode D4 being grounded, and the other end of the fourth inductor L4 being connected to the cathode of the third voltage-controlled varactor diode D3, where one end of the third inductor L3 serves as the input of the low-pass lumped phase shift unit, and the other end of the fourth inductor L4 serves as the output of the low-pass lumped phase shift unit. As can be seen, the low-pass lumped phase shift unit has a simple circuit structure and can provide stable phase shifting in a wide frequency range. Also, due to the mutual coupling effect between the third inductor L3 and the fourth inductor L4, the overall phase shifter has a compact structure, small area and low cost, and can be widely applied to RF/microwave/millimeter wave band wireless communication systems.

Further, the third inductor L3 and the fourth inductor L4 are both spiral inductors, thereby allowing the phase shifter to be more compact and have a greater Q value.

Further, the third inductor L3 and the fourth inductor L4 both have an inductance of R/ω₁, the third voltage-controlled varactor diode D3 has a capacitance of ½Rω₁ and the fourth voltage-controlled varactor diode D4 has a capacitance of 2/Rω₁, where R is the input impedance of the phase shifter and ω₁ is the center frequency of the low-pass lumped phase shift unit.

Beneficial effects: The invention discloses a continuously adjustable analog phase shifter that has the following beneficial effects compared with prior art:
1. The invention adopts a lumped phase shift unit, and utilizes the advantage of a small size of the lumped parametric circuit, thereby allowing the phase shifter to have a compact structure, small area, low cost and convenient integration.
2. The lumped phase shift units in the invention may be selected all as high-pass lumped phase shift units or low-pass lumped phase shift units as appropriate, thereby having a flexible circuit structure that can meet the requirements at various operation frequencies.
3. The lumped phase shift units in the invention may be selected to take the form of series-connected high-pass lumped phase shift unit and low-pass lumped phase shift unit, thereby permitting a wider bandwidth.
4. According to the invention, multiple lumped phase shift units can be connected in series to form an analog phase shifter with 360-degree continuously adjustable phase having a low insertion loss.

### BRIEF DESCRIPTION OF THE DRAWINGS

FIG. 1 (a) is a schematic view of a phase shifter enabling 180° phase shifting in prior art;

FIG. 1 (b) is a schematic view of a reflective circuit in prior art;

FIG. 1 (c) is a schematic view of a phase shifter enabling 360° phase shifting in prior art;

FIG. 2 is a schematic view of a phase shifter according to a particular embodiment of the invention;

FIG. 3 is a schematic view of a low-pass lumped phase shift unit according to a particular embodiment of the invention;

FIG. 4 is a schematic view of a high-pass lumped phase shift unit according to a particular embodiment of the invention;

FIGS. 5 (a) to 5 (c) are a diagram showing the simulation results of a phase shifter according to a particular embodiment of the invention;

FIG. 5 (a) is a diagram showing the simulation results of the input/output return loss of an analog phase shifter with 6-12 GHz 360-degree continuously adjustable phase;

FIG. 5 (b) is a diagram showing the simulation results of the insertion loss in various phase shift statuses of an analog phase shifter with 6-12 GHz 360-degree continuously adjustable phase; and

FIG. 5 (c) is a diagram showing the simulation results of the phase shift range of an analog phase shifter with 6-12 GHz 360-degree continuously adjustable phase at a control voltage of 0 to 10V.

### DETAILED DESCRIPTION

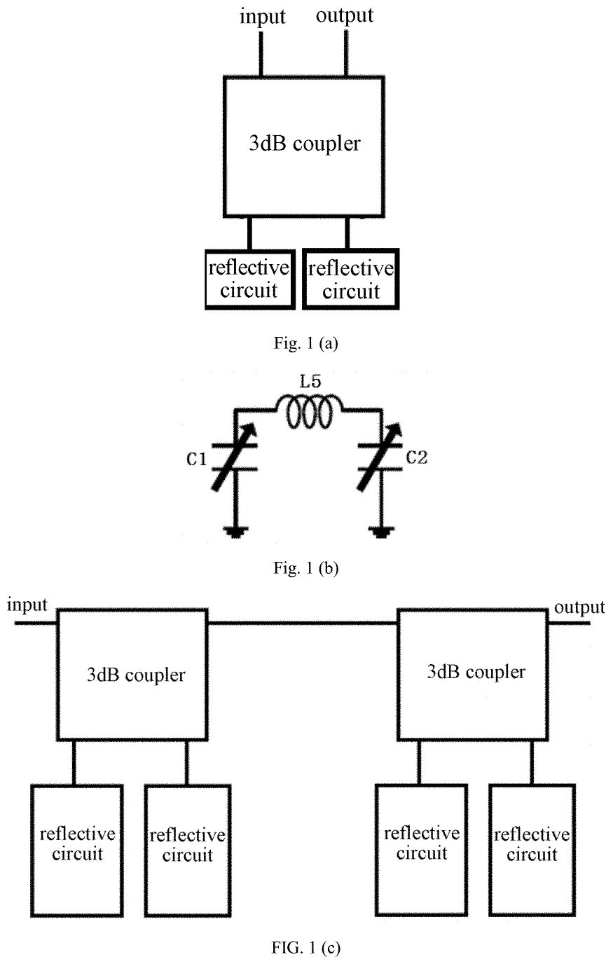

The phase shifter enabling 180° phase shafting in prior art, as shown in FIG. 1 (a), includes a 3 dB coupler with a varactor diode loaded at its terminal and a reflective circuit. The reflective circuit, as shown in FIG. 1 (b), includes a fifth inductor L5. One end of the fifth inductor L5 is connected to one end of a first variable capacitor C1. The other end of the first variable capacitor C1 is grounded. The other end of the fifth inductor L5 is connected to one end of the second variable capacitor C2. The other end of the second variable capacitor C2 is grounded. The phase shifter enabling 360° phase shafting in prior art, as shown in FIG. 1 (c), is formed by two 180° phase shifters that are connected in series. However, the 3 dB coupler has the disadvantages of large area, inconvenient integration, and increased circuit cost. The traditional reflective circuit can hardly meet the requirements of broadband and miniaturization.

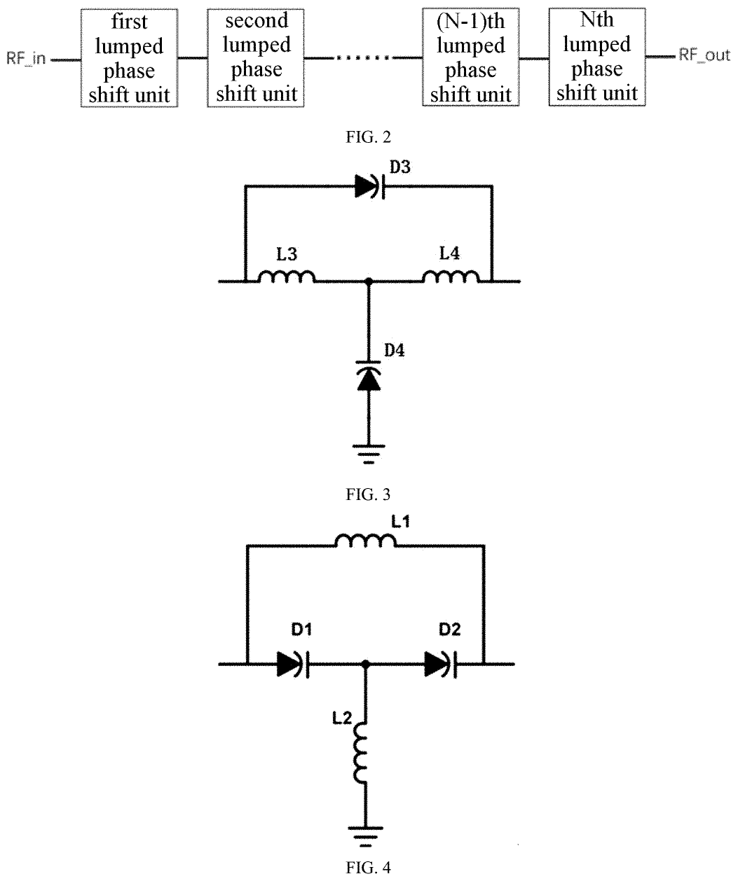

To overcome the disadvantages of prior art, this particular embodiment discloses a continuously adjustable analog phase shifter which, as shown in FIG. 2, includes N series-connected lumped phase shift units, with N≥1, among which the ith lumped phase shift unit is a high-pass lumped phase shift unit or a low-pass lumped phase shift unit, with 1≤i≤N.

As shown in FIG. 4, the high-pass lumped phase shift unit includes a first inductor L1. One end of the first inductor L1 is connected to the anode of the first voltage-controlled varactor diode D1. The cathode of the first voltage-controlled varactor diode D1 is connected respectively to one end of the second inductor L2 and the anode of the second voltage-controlled varactor diode D2. The other end of the second inductor L2 is grounded. The cathode of the second voltage-controlled varactor diode D2 is connected to the other end of the first inductor L1. One end of the first inductor L1 serves as the input of the high-pass lumped phase shift unit, and the other end of the first inductor L1 serves as the output of the high-pass lumped phase shift unit.

The first inductor L1 has an inductance of 2R/ω₀ and the second inductor L2 has an inductance of R/ω₀, and the first voltage-controlled varactor diode D1 and the second voltage-controlled varactor diode D2 both have a capacitance of 1/Rω₀, where R is the input impedance of the phase shifter and coo is the center frequency of the high-pass lumped phase shift unit. The input impedance of the phase shifter is equal to the output impedance, typically 50 Ohm.

As shown in FIG. 3, the low-pass lumped phase shift unit includes a third inductor L3. One end of the third inductor L3 is connected to the anode of the third voltage-controlled varactor diode D3. The other end of the third inductor L3 is connected respectively to one end of the fourth inductor L4 and the cathode of the fourth voltage-controlled varactor diode D4. The anode of the fourth voltage-controlled varactor diode D4 is grounded. The other end of the fourth inductor L4 is connected to the cathode of the third voltage-controlled varactor diode D3. One end of the third inductor L3 serves as the input of the low-pass lumped phase shift unit and the other end of the fourth inductor L4 serves as the output of the low-pass lumped phase shift unit.

The third inductor L3 and the fourth inductor L4 both have an inductance of R/ω₁, the third voltage-controlled varactor diode D3 has a capacitance of ½Rω₁ and the fourth voltage-controlled varactor diode D4 has a capacitance of 2/Rω₁, where R is the input impedance of the phase shifter and ω₁ is the center frequency of the low-pass lumped phase shift unit.

The phase response θ(ω) of a single low-pass lumped phase shift unit is expressed in the equation (2), where is expressed in the equation (3).

$$\begin{matrix} θ ( ω ) = 2 {tan}^{- 1} ( \frac{{ωω}_{c}}{{ω}^{2} - {ω}_{c}^{2}} ) & ( 2 ) \\ {ω}_{c} = ω \text{?} \sqrt{\frac{{C}_{n , i}}{{C}_{i}}} \\ \text{?} \text{indicates text missing or illegible when filed} & ( 3 )\end{matrix}$$

In the equation (3), is the initial capacitance of the ith voltage-controlled varactor diode at a control voltage of 0V, with 1=3 or 4. When 1=3, C_{n,3} is the initial capacitance of the third voltage-controlled varactor diode D3 at a control voltage of 0V. When i=4, C_{n,4} is the initial capacitance of the fourth voltage-controlled varactor diode D4 at a control voltage of 0V. Cᵢ is the maximum capacitance of the ith voltage-controlled varactor diode. When 1=3, C₃ is the maximum capacitance of the third voltage-controlled varactor diode D3. When 1=4, C₄ is the maximum capacitance of the fourth voltage-controlled varactor diode D4. ω_{c} is the resonant frequency at the time when the capacitance of the third voltage-controlled varactor diode D3 changes from C_{n,3} to C₃ as the control voltage changes, and is also the resonant frequency at the time when the capacitance of the fourth voltage-controlled varactor diode D4 changes from C_{n,4} to C₄ as the control voltage changes. For a single low-pass lumped phase shift unit, the maximum phase shift occurs in the maximum range of capacitance change, i.e., Cₘᵢₙ to Cₘₐₓ. Therefore, the size of the third voltage-controlled varactor diode D3 and the fourth voltage-controlled varactor diode D4 can be selected based on the desired phase shift range and the return loss.

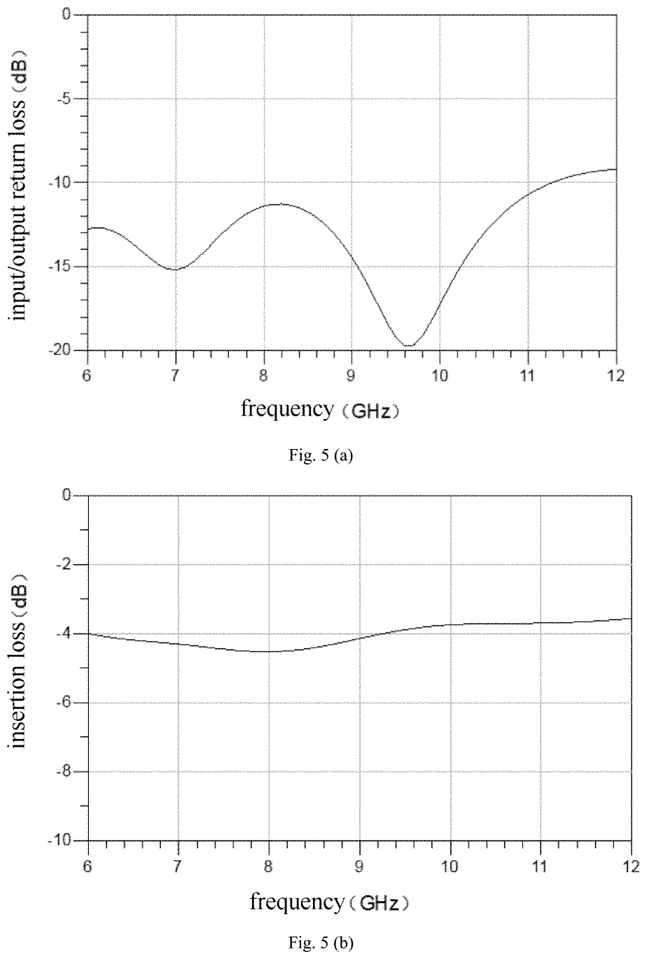

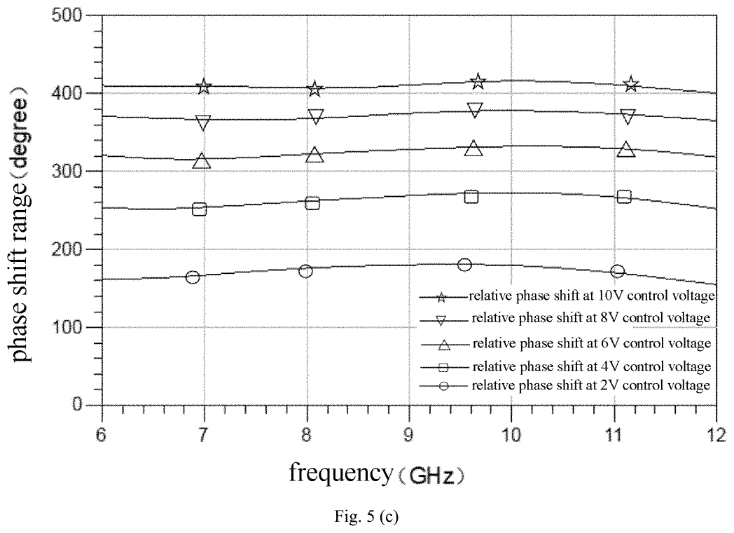

In the field of phased arrays, all-band 360° accumulative phase shifting is typically desired. Therefore, a series connection of multi-stage lumped phase shift units is often desired. By the series connection of lumped phase shift units of different center frequencies, not only is phase shift increased, but also wide bandwidth and flat phase shift response are enabled. For example, in a phase shifter with four low-pass lumped phase shift units, two of which are low-pass lumped phase shift units of a center frequency of 6 GHz and the other two of which are low-pass lumped phase shift units of a center frequency of 12 GHz, the initial values of various lumped phase shift units in the analog phase shifter with 6-12 GHz all-band 360° continuously adjustable phase can be determined and locally optimized to achieve the aim. FIGS. 5 (a) to 5 (c) are diagrams showing the simulation results of an analog phase shifter with 6-12 GHz all-band 360° continuously adjustable phase. As shown in FIG. 5 (a), the return loss of the phase shifter has a typical value of −13 dB, which represents a desirable return characteristic. As shown in FIG. 5 (b), the insertion loss of the phase shifter has a typical value of −4 dB, which is very low and represents a desirable linearity. As shown in FIG. 5 (c), the phase shifter enables a phase shift range greater than 360 degrees over 6-12 GHz all band with little phase shift fluctuation.

What is claimed is:

1. A continuously adjustable analog phase shifter, comprising N series-connected lumped phase shift units, with N≥1, where the ith lumped phase shift unit is a high-pass lumped phase shift unit or a low-pass lumped phase shift unit, with 1≤i≤N.

2. The continuously adjustable analog phase shifter of claim 1, wherein the high-pass lumped phase shift unit comprises a first inductor L1, one end of the first inductor L1 being connected to the anode of a first voltage-controlled varactor diode D1, the cathode of the first voltage-controlled varactor diode D1 being connected respectively to one end of the second inductor L2 and the anode of a second voltage-controlled varactor diode D2, the other end of the second inductor L2 being grounded, the cathode of the second voltage-controlled varactor diode D2 being connected to the other end of the first inductor L1; where one end of the first inductor L1 serves as the input of the high-pass lumped phase shift unit and the other end of the first inductor L1 serves as the output of the high-pass lumped phase shift unit.

3. The continuously adjustable analog phase shifter of claim 2, wherein the first inductor L1 and the second inductor L2 are both spiral inductors.

4. The continuously adjustable analog phase shifter of claim 2, wherein the first inductor L1 has an inductance of 2R/ω₀ and the second inductor L2 has an inductance of R/ω₀, and the first voltage-controlled varactor diode D1 and the second voltage-controlled varactor diode D2 both have a capacitance of 1/Rω₀, where R is the input impedance of the phase shifter and ω₀ is the center frequency of the high-pass lumped phase shift unit.

5. The continuously adjustable analog phase shifter of claim 1, wherein the low-pass lumped phase shift unit comprises a third inductor L3, one end of the third inductor L3 being connected to the anode of the third voltage-controlled varactor diode D3, and the other end of the third inductor L3 being connected respectively to one end of the fourth inductor L4 and the cathode of the fourth voltage-controlled varactor diode D4, the anode of the fourth voltage-controlled varactor diode D4 being grounded, and the other end of the fourth inductor L4 being connected to the cathode of the third voltage-controlled varactor diode D3, where one end of the third inductor L3 serves as the input of the low-pass lumped phase shift unit, and the other end of the fourth inductor L4 serves as the output of the low-pass lumped phase shift unit.

6. The continuously adjustable analog phase shifter of claim 5, wherein the third inductor L3 and the fourth inductor L4 are both spiral inductors.

7. The continuously adjustable analog phase shifter of claim 5, wherein the third inductor L3 and the fourth inductor L4 both have an inductance of R/ω₁, the third voltage-controlled varactor diode D3 has a capacitance of ½Rω₁ and the fourth voltage-controlled varactor diode D4 has a capacitance of 2/Rω₁, where R is the input impedance of the phase shifter and ω₁ is the center frequency of the low-pass lumped phase shift unit.
